(19) United States
(12) Patent Application Publication
(10) Pub. No.: US 2024/0290849 A1
(43) Pub. Date: Aug. 29, 2024

(54) WRAP-AROUND SILICIDE LAYER

(71) Applicant: Taiwan Semiconductor Manufacturing Company, Ltd., Hsinchu (TW)

(72) Inventors: Meng-Huan Jao, Taichung City (TW); Chun-Yuan Chen, HsinChu (TW); Huan-Chieh Su, Changhua County (TW); Chih-Hao Wang, Hsinchu County (TW)

(21) Appl. No.: 18/324,729

(22) Filed: May 26, 2023

Related U.S. Application Data
(60) Provisional application No. 63/486,813, filed on Feb. 24, 2023.

(51) Int. Cl. H01L 29/417; H01L 21/8234; H01L 27/088; H01L 29/06; H01L 29/423; H01L 29/49; H01L 29/66; H01L 29/775; H01L 29/786

(52) U.S. Cl. CPC H01L 29/41733; H01L 21/823412; H01L 21/823418; H01L 21/823468; H01L 27/088; H01L 29/0673; H01L 29/42392; H01L 29/4975; H01L 29/66439; H01L 29/6656; H01L 29/775; H01L 29/78696

(57) ABSTRACT

Semiconductor structures and processes are provided. A semiconductor structure according to the present disclosure includes a channel region of a semiconductor body rising above an isolation feature, a gate structure wrapping over the channel region, a source/drain feature in contact with a sidewall of the channel region, a backside silicide layer disposed on a bottom surface of the source/drain feature, and a backside contact feature extending through the isolation feature to contact a bottom surface of the backside silicide layer. A sidewall of the backside contact feature is spaced apart from the isolation feature by a first backside contact etch stop layer (CESL) and a second backside CESL.

### PRIORITY DATA

This application claims benefit of U.S. Provisional Patent Application Ser. No. 63/486,813, filed Feb. 24, 2023, the entirety of which is incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

Silicide layers are implemented at interfaces between source/drain contacts and epitaxial source/drain features to reduce contact resistance. Gate pitches shrink as dimensions of semiconductor devices continue to decrease. The smaller gate pitches create challenges in silicide formation.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor device having a wrap-around silicide layer, according to one or more aspects of the present disclosure.

FIGS. 2-15 illustrate fragmentary cross-sectional views of a workpiece during a fabrication process according to the method of FIG. 1, according to one or more aspects of the present disclosure.

FIGS. 16-21 illustrates fragmentary cross-sectional views of semiconductor devices according to various example embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

Transistors on modern-day IC devices include planar transistors or multi-gate transistors. A planar device refers to a device having a gate structure that engages a planar surface of a semiconductor active region. Multi-gate devices refer to those whose gate structures are formed on at least two-sides of a channel region. Examples of multi-gate devices include fin-like field effect transistors (FinFETs) having fin-like structures and MBC transistors having a plurality of a channel members. As described above, MBC transistors may also be referred to as SGTs, GAA transistors, nanosheet transistors, or nanowire transistors. These multi-gate devices may be either n-type or p-type. An MBC transistor includes any device that has its gate structure, or portion thereof, formed on 4-sides of a channel region (e.g., surrounding a portion of a channel region). MBC devices may have channel regions disposed in nanowire channel members, bar-shaped channel members, nanosheet channel members, nanostructure channel members, bridge-shaped channel members, and/or other suitable channel configurations. Both planar devices and multi-gate devices may include epitaxially grown source/drain features that may extend vertically and laterally beyond top surfaces and sidewalls of the active region. A silicide layer is formed at an interface between a source/drain feature and a metal contact feature to reduce contact resistance. In some existing processes, one or more dielectric layer is deposited over a source/drain feature and an opening is formed in the one or more dielectric layer to expose a portion of the source/drain feature. A pre-clean process and silicide formation are then performed with respect to the exposed portion in the opening. As gate pitches continue to shrink, these existing processes may run into challenges in forming a silicide layer satisfactorily.

The present disclosure provides a process and a structure to form wrap-around silicide layer that wraps over a top surface and sidewalls of source/drain features. In an example embodiment, after a source/drain feature is epitaxially deposited, a first contact etch stop layer (CESL) and a first interlayer dielectric (ILD) layer are deposited over the source/drain feature. The first ILD layer is selectively etched away with a wet etching process and the first CESL is anisotropically etched to expose the top surface and sidewalls of the source/drain feature. A silicide layer is then deposited to wrap over the source/drain feature. Thereafter, a second CESL and a second ILD layer are deposited over the silicide layer. Because the silicide layer is formed between the first CESL and the second CESL, the process may also be referred to as a silicide-middle process or salicide-middle process. Due to the fact that the wrap-around silicide layer is formed on a larger exposed surface, the process has an improved process window. The additional contact surface between the wrap-around silicide layer and the source/drain feature also reduces contact resistance.

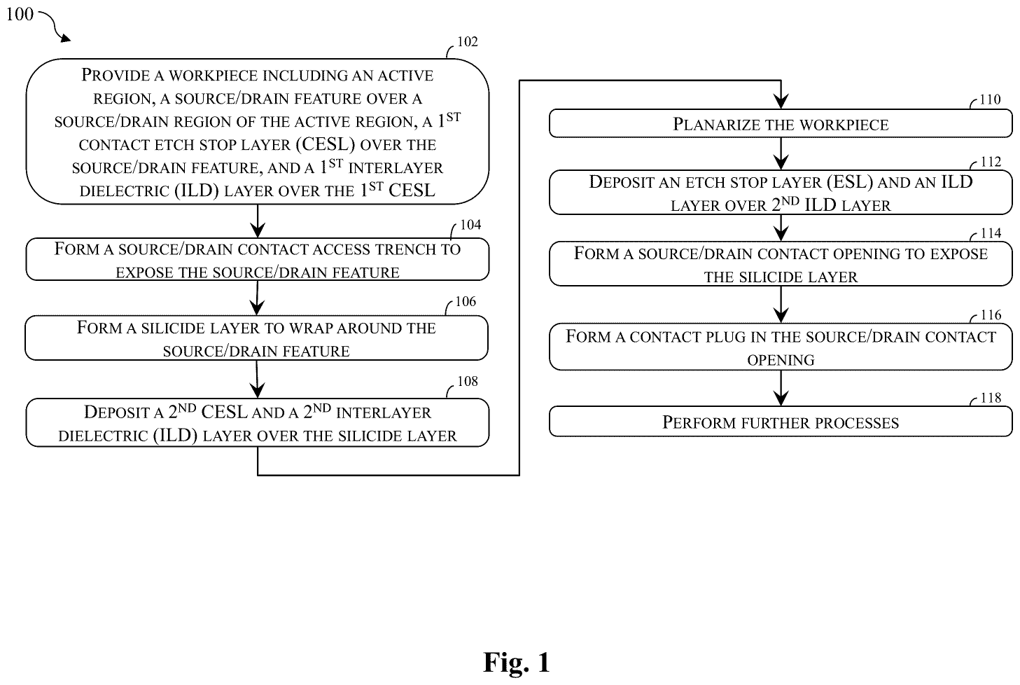

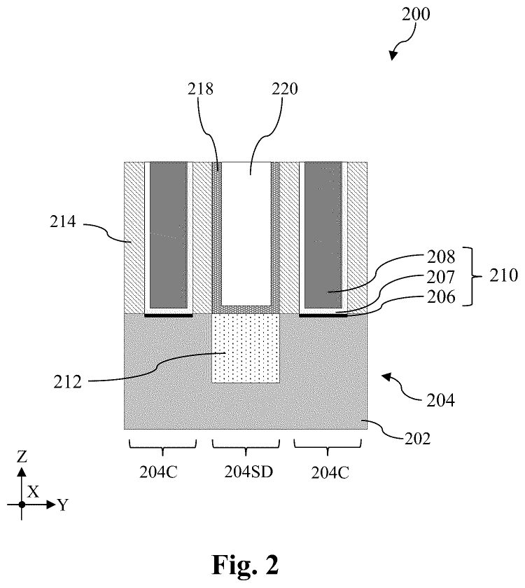

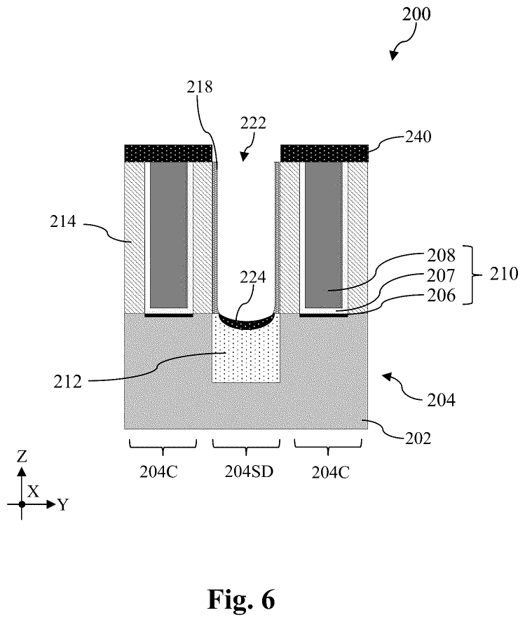

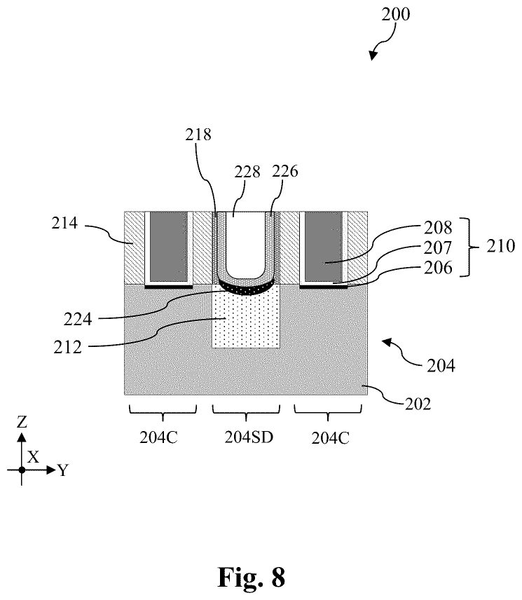

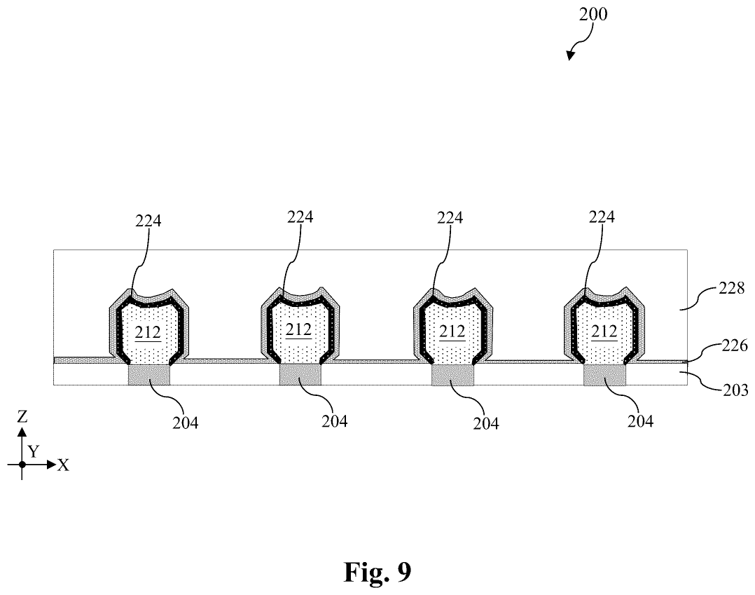

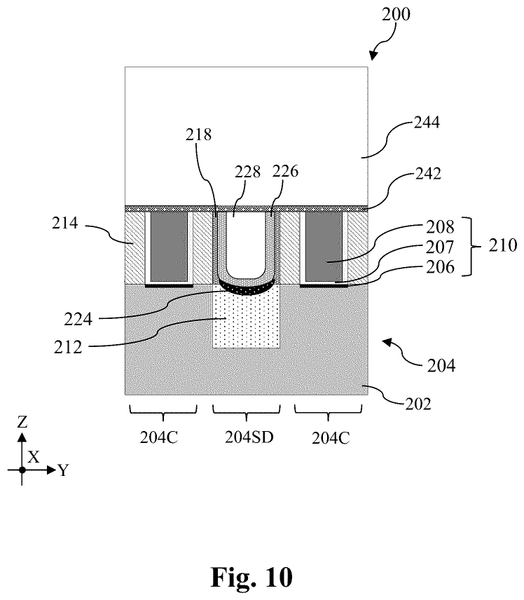

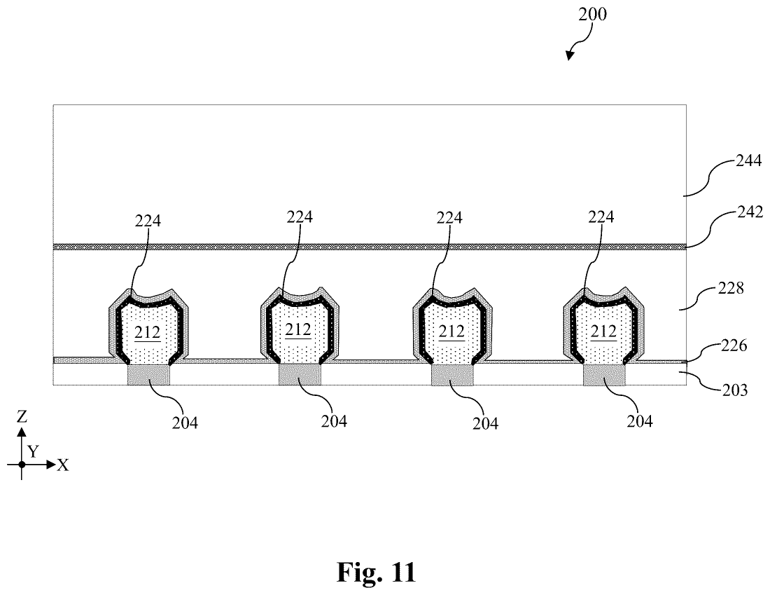

The various aspects of the present disclosure will now be described in more detail with reference to the figures. In that regard, FIG. 1 is a flowchart illustrating method 100 of forming a semiconductor structure 200 from a workpiece 200 according to embodiments of the present disclosure. Method 100 is merely an example and is not intended to limit the present disclosure to what is explicitly illustrated in method 100. Additional steps can be provided before, during and after the method 100, and some steps described can be replaced, eliminated, or moved around for additional embodiments of the method. Not all steps are described herein in detail for reasons of simplicity. Method 100 is described below in conjunction with FIGS. 2-13, which are fragmentary cross-sectional views of the workpiece at different stages of fabrication according to embodiments of method 100. Throughout the present application, similar reference numerals reference similar features unless otherwise excepted in the specification. Additionally, X, Y and Z directions are perpendicular to one another and are intended to be used consistently throughout the figures.

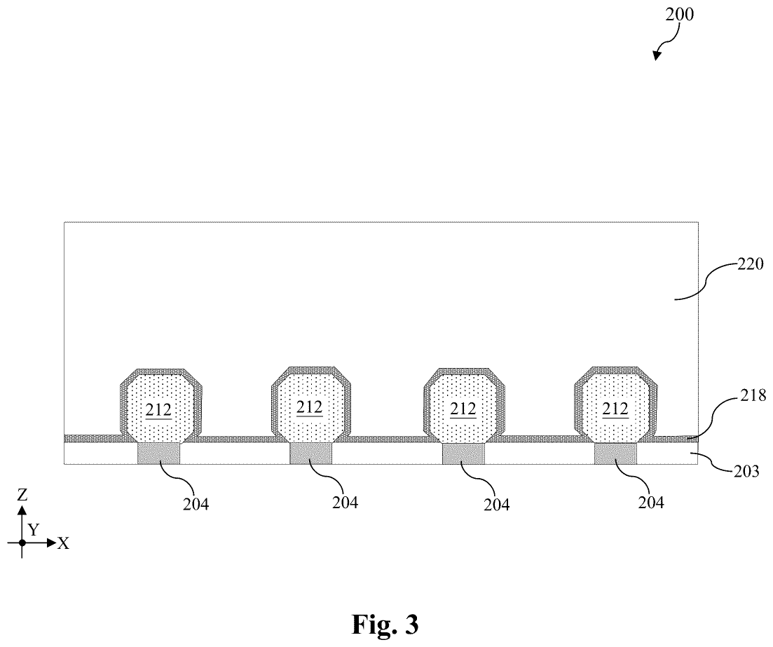

Referring to FIGS. 1, 2 and 3, method 100 includes a block 102 where a workpiece 200 is provided. As shown in FIGS. 2 and 3, the workpiece 200 includes a substrate 202. Over the substrate 202, the workpiece 200 includes a fin structure 204 rising from the substrate 202. Gate structures 210 are formed to wrap over the fin structure 204 such that the each of the gate structures 210 engages a top surface and sidewalls of the fin structure 204. The formation of the fin structure 204 may include etching the substrate 202. As shown in FIG. 2, the fin structure 204 may be divided into channel regions 204C under gate structures 210 and source/drain regions 204SD that are not overlapped by a gate structure 210. The workpiece 200 also includes a source/drain feature 212 formed over the source/drain region 204SD. In the depicted embodiments, the source/drain feature 212 is formed in a source/drain recess over the source/drain region 204SD. The source/drain features 212 are disposed over source/drain regions 204SD and the gate structure 210 is disposed over a channel region 204C. As shown in FIG. 3, base portions of the fin structures 204 are surrounded by an isolation feature 203, which is deposited on a top surface of the substrate 202. A first contact etch stop layer (CESL) 218 is disposed over surfaces of the source/drain feature 212 and a first interlayer dielectric (ILD) layer 220 is deposited over the first CESL 218 to fill the gaps. The gate structures 210 are spaced apart from the first CESL 218 by a gate spacer 214. The gate spacer 214 is disposed over the fin structure 204 and extends along sidewalls of the gate structure 210.

The substrate 202 may include an elementary (single element) semiconductor, such as silicon (Si), germanium (Ge), and/or other suitable materials; a compound semiconductor (i.e., alloy semiconductor), such as silicon carbide (SiC), gallium arsenic (GaAs), gallium phosphide (GaP), indium phosphide (InP), indium arsenide (InAs), indium antimonide (InSb), silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), gallium indium phosphide (GaInAsP), and/or other suitable materials. The substrate 202 may be a single-layer material having a uniform composition. Alternatively, the substrate may include multiple material layers having similar or different compositions suitable for IC device manufacturing. In one example, the substrate may be a silicon-on-insulator (SOI) substrate having a silicon layer formed on a buried silicon oxide (BOX) layer. In some embodiments, the substrate includes various doped regions, such as n-type wells or p-type wells. The doped regions may be doped with n-type dopants, such as phosphorus (P) or arsenic (As), and/or p-type dopants, such as boron (B) or BF₂, depending on design requirements. Doped regions may be formed by implantation of dopant atoms, in-situ doped epitaxial growth, and/or other suitable techniques. In the depicted embodiments, the substrate 202 includes silicon (Si).

The isolation feature 203 may also be referred to as a shallow trench isolation (STI) feature 203. The isolation feature 203 may include silicon oxide, silicon nitride, silicon oxynitride, fluorine-doped silicate glass (FSG), a low-k dielectric, combinations thereof, and/or other suitable materials. The gate spacer 214 may be a single layer or a multi-layer. In some instances, the gate spacer 214 may include silicon oxide, silicon oxycarbide, silicon carbonitride, silicon nitride, zirconium oxide, aluminum oxide, a suitable low-k dielectric material, or a suitable dielectric material. The metal oxides here may include aluminum oxide, zirconium oxide, tantalum oxide, yttrium oxide, titanium oxide, lanthanum oxide, or other suitable metal oxide. Depending on the type of the devices, the source epitaxial feature 212 may be n-type or p-type. When the source/drain feature 212 is n-type, it includes silicon (Si) doped with an n-type dopant, such as phosphorus (P) or arsenide (As). When the source/drain feature 212 is p-type, it includes silicon germanium (SiGe) doped with a p-type dopant, such as boron (B).

The gate structure 210 includes an interfacial layer 206, a gate dielectric layer 207 over the interfacial layer 206, and a gate electrode 208 over the gate dielectric layer 207. In some embodiments, the interfacial layer 206 includes silicon oxide and may be formed on semiconductor surfaces (such as silicon surfaces of the fin structure 204) in a pre-clean process. An example pre-clean process may include use of RCA SC-1 (ammonia, hydrogen peroxide and water) and/or RCA SC-2 (hydrochloric acid, hydrogen peroxide and water). The gate dielectric layer 207 may include a high-k dielectric material that has a dielectric material with a dielectric constant greater than that of silicon dioxide, which is about 3.9. In some instances, the gate dielectric layer 207 may include hafnium oxide (HfO), titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. In one embodiment, the gate dielectric layer 207 includes hafnium oxide. The gate electrode 208 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof.

In some embodiments, the first CESL 218 is first conformally deposited on the workpiece 200, including over the source/drain feature 212, using ALD or CVD. The first ILD layer 220 is deposited over the first CESL 218 by spin-on coating, FCVD. CVD, or other suitable deposition technique. The first ILD layer 220 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the first ILD layer 220, the workpiece 200 may be annealed to improve integrity of the first ILD layer 220.

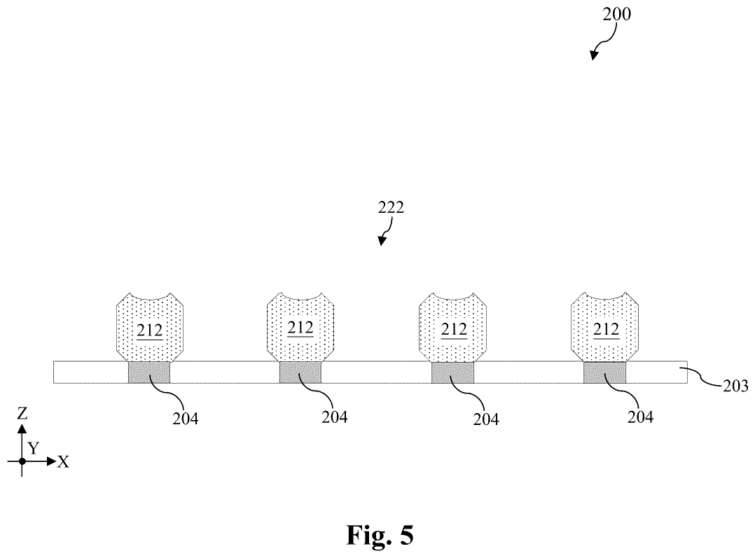

Referring still to FIGS. 1, 4 and 5, method 100 includes a block 104 where a source/drain access trench 222 are formed. To form the source/drain access trench 222, a patterned hard mask 240 is formed over the workpiece 200. The patterned hard mask 240 includes openings that correspond to the source/drain access trench 222. The patterned hard mask 240 may be a single layer or a multilayer. Although not explicitly shown in the figures, the patterned hard mask 240 may be a multilayer that includes a tungsten carbide layer, a silicon nitride layer, and/or an amorphous silicon (a-Si) layer. Each of the hard mask layers in the patterned hard mask may be deposited using physical vapor deposition (PVD), CVD, ALD, or a suitable deposition method to form a hard mask 240. To pattern the hard mask 240, a photoresist layer is deposited over the hard mask 240. The photoresist layer is patterned using a photolithography process. The photolithography process may include soft baking, mask aligning, exposure, post-exposure baking, photoresist developing, rinsing, drying (e.g., spin-drying and/or hard baking), other suitable lithography techniques, and/or combinations thereof. The patterned photoresist layer is then applied as an etch mask to etch the underlying hard mask 240 to form the patterned hard mask 240. Because the cross-sectional view in FIG. 5 cuts through the source/drain access trench 222, the patterned hard mask 240 is not shown in FIG. 5. Along the Y direction (i.e., the lengthwise direction of the fin structure 204), the source/drain access trench 222 is confined between the leftover first CESL 218. Along the X direction (i.e., the lengthwise direction of the gate structure 210), the source/drain access trench 222 is elongated and exposes multiple source/drain features 212.

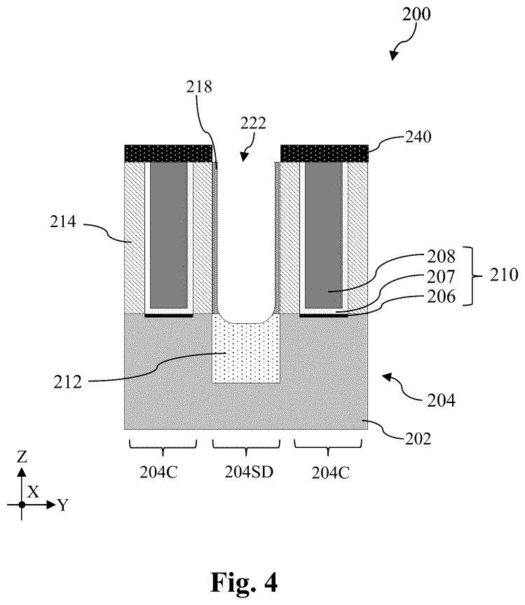

After formation of the patterned hard mask 240, the first ILD layer 220 is selectively etched away using an isotropic wet etching process. In some embodiments, the isotropic wet etch may be a buffered oxide etch (BOE) that uses hydrofluoric acid (HF) and ammonium fluoride (NH₄F). In some other embodiments, the isotropic wet etch may include use of dilute hydrofluoric acid (DHF). In embodiments where the first CESL 218 is formed of silicon nitride or silicon oxynitride, the selective wet etch is capable of substantially etching away the first ILD layer 220 without substantially etching the first CESL 218. After the first ILD layer 220 is etched away, an anisotropic etch process is performed to breach the first CESL 218 so as to expose the source/drain feature 212 in the source/drain access trench 222. For example, the anisotropic etch process may be a reactive-ion etching (RIE) process that includes use of a bromine-containing gas (e.g., HBr and/or CHBr₃), a fluorine-containing gas (e.g., CF₄, SF₆, NF₃, CH₂F₂, CHF₃, and/or C₂F₆), a carbon-containing gas (e.g., CH₄ or C₂H₆), other suitable gases, or combinations thereof. As shown in FIGS. 4 and 5, the anisotropic etch process may etch a portion of the source/drain feature 212, thereby forming a recess.

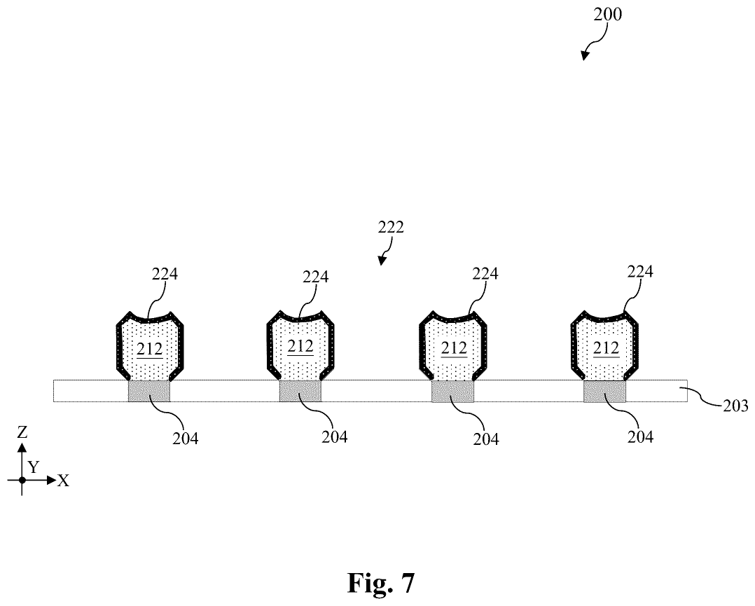

Referring to FIGS. 1, 6 and 7, method 100 includes a block 106 where a silicide layer 224 is formed to wrap around the exposed source/drain features 212. To prepare the exposed surfaces of the source/drain features 212 for silicide formation, a cleaning process may be performed to remove oxide contamination on the source/drain features 212. The cleaning process may be a dry clean process that includes use of argon plasma, NH₃ and/or NF₃ or a wet clean process that includes use of RCA SC-1 (ammonia, hydrogen peroxide and water) and/or RCA SC-2 (hydrochloric acid, hydrogen peroxide and water). As shown in FIG. 7, after the exposed surfaces are cleaned, the silicide layer 224 is deposited to wrap over a top surface and sidewalls of the source/drain feature 212. The silicide layer 224 may include titanium silicide (TiSi), zirconium silicide (ZrSi), antimony silicide (SbSi), bismuth silicide (BiSi), nickel silicide (NiSi), tin silicide (SnSi), or molybdenum silicide (MoSi). In some embodiments, the silicide layer 224 may consist essentially of one of the metal silicide described above. For example, the silicide layer 224 may consist essentially of titanium silicide (TiSi). There are at least two processes to form the silicide layer 224. A first process includes deposition of a metal precursor layer and silicidation between the metal precursor layer and the source/drain feature 212. A second process may include an ALD or a CVD that includes use of a metal-containing precursor and a silicon containing precursor. When the first process is adopted, the metal precursor layer is first deposited using PVD and then an anneal, with an anneal temperature between about 400° C. and about 600° C., is performed to bring about the silicidation reaction. The excess metal precursor layer that does not turn silicide may be selectively removed afterwards, leaving only the silicide layer 224. When the second process is adopted, a metal-containing precursor (e.g., titanium tetrachloride, zirconium tetrachloride, antimony trichloride, bismuth trichloride, nickel chloride, tin chloride, or molybdenum pentachloride) and a silicon containing precursor (e.g., silane or disilane) may be used to deposit the silicide layer 224 using CVD or ALD. In the depicted embodiment, the second process is used to form the silicide layer 224.

Referring to FIGS. 1, 8 and 9, method 100 includes a block 108 where a second CESL 226 and a second ILD layer 228 are deposited over the silicide layer 224. After the formation of the silicide layer 224, the second CESL 226 and the second ILD layer 228 are sequentially deposited over the workpiece 200, including over the source/drain access trench 222. In some embodiments, the second CESL 226 shares the same composition with the first CESL 218 and may be deposited using ALD or CVD. The second ILD layer 228 shares the same composition with the first ILD layer 220 and may be deposited using FCVD, spin-in coating, or CVD.

Referring to FIGS. 1, 8 and 9, method 100 includes a block 110 where the workpiece 200 is planarized. After the deposition of the second CESL 226 and the second ILD layer 228, the workpiece 200 is planarized to remove the patterned hard mask 240 and provide a planar top surface. In some embodiments, the planarization includes a chemical mechanical polishing (CMP) process.

Referring to FIGS. 1, 10 and 11, method 100 includes a block 112 where an etch stop layer (ESL) 242 and an ILD layer 244 are deposited over the workpiece 200. After the top surfaces of the workpiece 200 is planarized, the ESL 242 is deposited on the planar surface of the workpiece 200 and the ILD layer 244 is deposited on the ESL 242. In some embodiments, the ESL 242 may include silicon nitride or silicon oxynitride and may be deposited using CVD. The ILD layer 244 may deposited using FCVD, spin-on coating, or CVD and may include silicon oxide, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

Referring to FIGS. 1, 12 and 13, method 100 includes a block 114 where a source/drain contact opening 230 is formed to expose the silicide layer 224. To form the source/drain contact opening 230, a patterned hard mask (not explicitly shown in the figures) is formed on the ILD layer 244. The patterned hard mask includes an opening that corresponds to the source/drain contact opening 230. The patterned hard mask here, like the patterned hard mask 240 described above, may be a single layer or a multilayer. In some embodiments, the patterned hard mask may be a multilayer that includes a tungsten carbide layer, a silicon nitride layer, and/or an amorphous silicon (a-Si) layer. Each of the hard mask layers in the patterned hard mask may be deposited using physical vapor deposition (PVD), CVD, ALD, or a suitable deposition method. To pattern the hard mask, a photoresist layer is deposited over the hard mask. The photoresist layer is patterned using a photolithography process. The photolithography process may include soft baking, mask aligning, exposure, post-exposure baking, photoresist developing, rinsing, drying (e.g., spin-drying and/or hard baking), other suitable lithography techniques, and/or combinations thereof. The patterned photoresist layer is then applied as an etch mask to etch the underlying hard mask to form the patterned hard mask. After formation of the patterned hard mask, an anisotropic etch process is performed to etch through the ILD layer 244, the ESL 242, the second ILD layer 228, and the second CESL 226 to expose the silicide layer 224. For example, the anisotropic etch process may be a reactive-ion etching (RIE) process that includes use of a bromine-containing gas (e.g., HBr and/or CHBr₃), a fluorine-containing gas (e.g., CF₄, SF₆, NF₃, CH₂F₂, CHF₃, and/or C₂F₆), a carbon-containing gas (e.g., CH₄ or C₂H₆), other suitable gases, or combinations thereof.

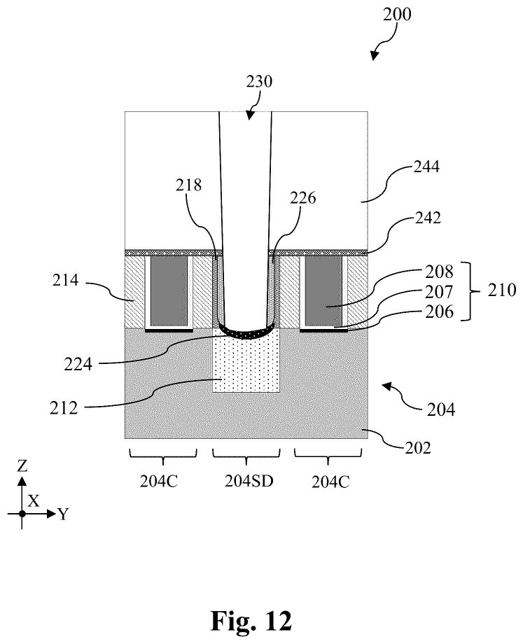

Referring to FIG. 12, the source/drain contact opening 230 extends through the ILD layer 244, the ESL 242, and the second CESL 226. When viewed along the X direction (i.e., lengthwise direction of the gate structures 210), a lower portion of the source/drain contact opening 230 is defined between two portions of the second CESL 226. The source/drain contact opening 230 is spaced apart from the leftover first CESL 218 by the leftover second CESL 226. Because the second CESL 226 is deposited after the silicide layer 224 is formed, the second CESL 226 is disposed directly on a top surface of the silicide layer 224. In other words, when viewed along the X direction, the silicide layer 224 undercuts the second CESL 226.

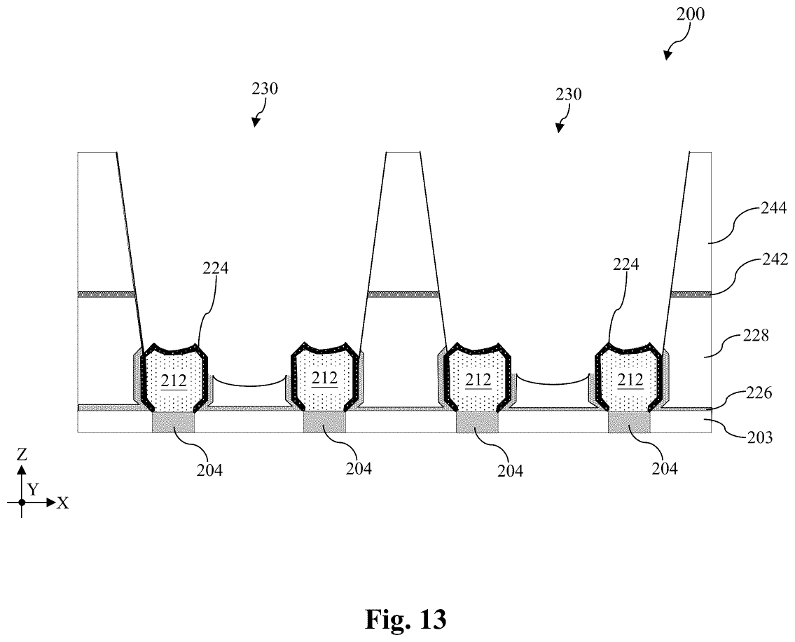

Referring now to FIG. 13, each of the source/drain contact openings 230 exposes silicide layer 224 deposited on two source/drain features 212. As shown in FIG. 13, the silicide layer 224 wraps around the top surfaces and sidewalls of the source/drain features 212, when viewed along the Y direction (i.e., lengthwise direction of the fin structure 204). In FIG. 13, the silicide layer 224 disposed on sidewalls of the source/drain features 212 is spaced apart from the second ILD layer 228 by the second CESL 226. The anisotropic etch process at block 114 also etches the second ILD layer 228 between two source/drain features 212 to a level below top surfaces of the source/drain features 212.

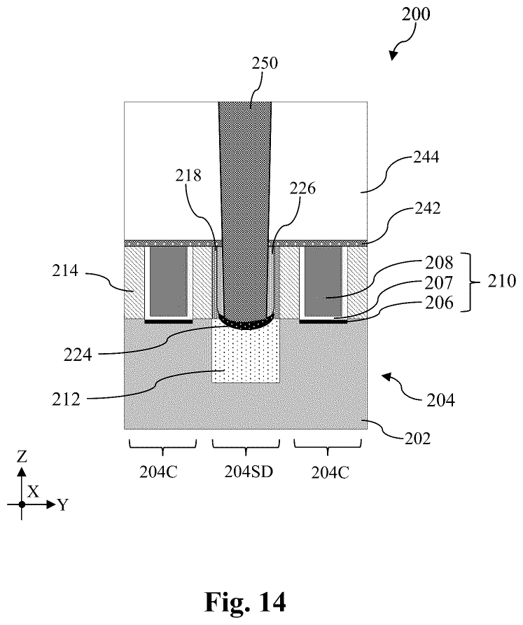

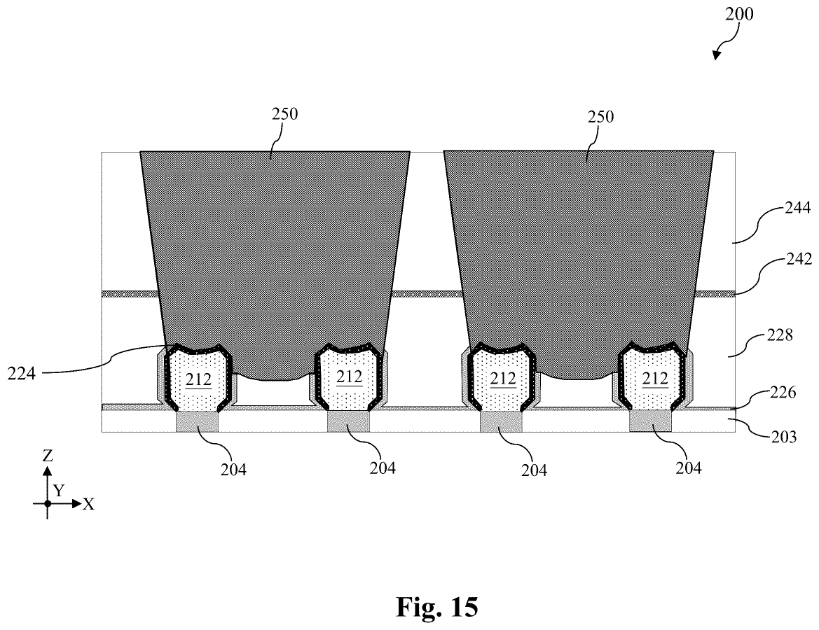

Referring to FIGS. 1, 14 and 15, method 100 includes a block 116 where a contact plug 250 is formed in the source/drain contact opening 230. The contact plug 250 may include a barrier layer and a metal fill layer. To prevent electromigration or oxygen diffusion from the ILD layer 244, a barrier layer may be formed along sidewalls of the source/drain contact opening 230. The barrier layer may include titanium (Ti), titanium nitride (TiN), tantalum (Ta), or tantalum nitride (TaN) and may be deposited using ALD, CVD, or PVD. The metal fill layer may include ruthenium (Ru), nickel (Ni), cobalt (Co), copper (Cu), molybdenum (Mo), tungsten (W), and may be deposited using PVD. CVD. ALD, electroplating, or electroless plating. After the deposition of the metal fill layer into the source/drain contact opening 230, the workpiece 200 is planarized by a planarization process, such as a chemical mechanical polishing (CMP) process, to remove excess materials and to form the contact plug 250. As shown in FIG. 14, after the planarization process, top surfaces of the ILD layer 244 and the contact plug 250 may be coplanar. In some instances, the silicide layer 224 may have a thickness between about 1 nm and about 10 nm. Referring to FIG. 15, when viewed along the Y direction, the contact plug 250 tracks a profile of the source/drain contact opening 230. The contact plug 250 engages the silicide layer 224 disposed on the top surface and sidewalls of the source/drain features 212. A portion of the contact plug 250 extends between the two source/drain features 212 exposed in the source/drain contact opening 230. A bottom surface of the contact plug 250 is lower than a top surface of the source/drain features 212 it connects to. Because the contact plug 250 engages the source/drain features 212 from a front side of the workpiece 200, it may also be referred to as a frontside contact plug 250.

Referring to FIG. 1, method 100 includes a block 118 where further processes are performed. Such further processes may include formation of interconnect structures or further contact features. For example, in addition to the contact plug 250 that electrically couples to the source/drain features 212 from a front side of the substrate 202, backside contact plugs 270 are formed to at least some of the source/drain features 212. To form the backside contact plugs 270, the substrate 202 may be ground and polished to reach a smaller thickness. Then operations similar to those for blocks 104 to 116 are performed with respect to a back side of the substrate 202 to form the backside contact plugs 270. While not explicitly shown in the figures, a portion of the substrate 202 may be removed and replaced with a backside dielectric layer. The backside dielectric layer and the isolation feature 203 may share the same composition.

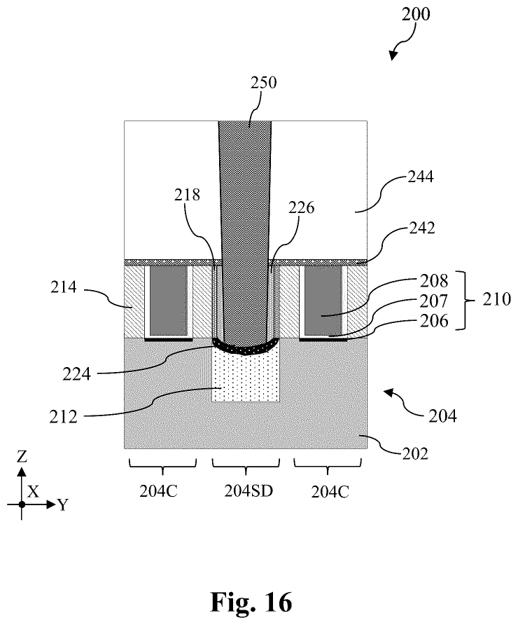

FIGS. 16-21 illustrate various alternative embodiments having configurations different from that shown in FIGS. 14 and 15. Reference is first made to FIG. 16. In some embodiments where the formation of the silicide layer 224 extends further into the source/drain feature 212, the silicide layer 224 may at least partially extend below the first CESL 218. That is, in the embodiment shown in FIG. 16, the silicide layer 224 under cuts not only the second CESL 226, but also the first CESL 218.

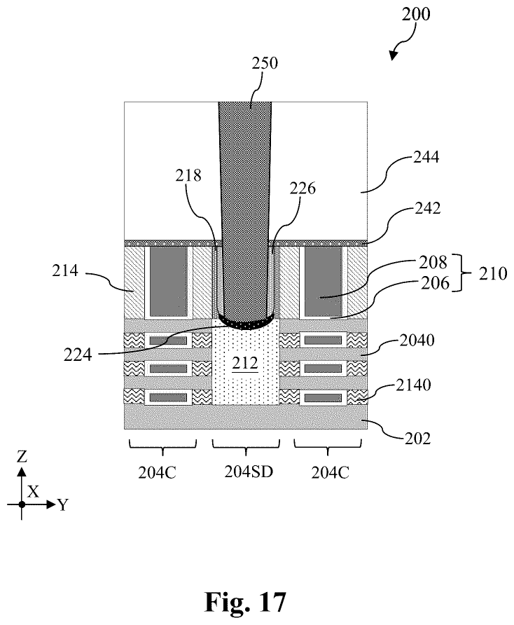

In some embodiments represented in FIG. 17, the semiconductor structure 200 includes MBC transistors, instead of FinFETs. As shown in FIG. 17, in these embodiments, the semiconductor structure 200 includes a vertical stack of nanostructures 2040 stacked one over another over channel regions 204C. The nanostructures 2040 may include silicon (Si) and depending on their shapes, they may also be referred to nanowires or nanosheets. The gate structure 210 wraps around each of the nanostructures 2040. As shown in FIG. 17, the gate structure 210 engages a top surface, sidewalls and a bottom surface of each of the nanostructures 2040. To space the gate structure 210 from the source/drain feature 212, a plurality of inner spacer features 2140 interleave the nanostructures 2040. The inner spacer features 2140 may include silicon oxynitride, silicon carbonitride, silicon oxycarbide, silicon oxycarbonitride, silicon nitride, carbon-rich silicon carbonitride, or a low-k dielectric material. A top portion of the gate structure 210 is defined between two gate spacers 214, which are disposed over the topmost nanostructures of the nanostructures 2040. End surfaces of the nanostructures 2040 are in direct contact with the source/drain features 212. The gate spacers 214 may include silicon oxide, silicon oxycarbide, silicon carbonitride, silicon nitride, zirconium oxide, aluminum oxide, a suitable low-k dielectric material, or a suitable dielectric material. Method 100 described above may be applicable to workpieces that include MBC transistors. After the gate structures 210 shown in FIG. 17 are formed, the first ILD layer 220 (removed and not shown in FIG. 17) in the source/drain region 204SD may be removed using an isotropic wet etching and an anisotropic etch is performed to etch the first CESL 218 in the source/drain regions 204SD, forming a source/drain access trench similar to the source/drain access trench 222 shown in FIG. 4. A silicide layer 224 is then formed to wrap over a top surfaces and sidewalls of the source/drain feature 212. Then a second CESL 226 and a second ILD layer 228 (removed and not shown in FIG. 17) are deposited over the source/drain access trench. After deposition of the ESL 242 and the ILD layer 244, a source/drain contact opening is formed to expose the silicide layer 224. A contact plug 250 is then formed in the source/drain contact opening.

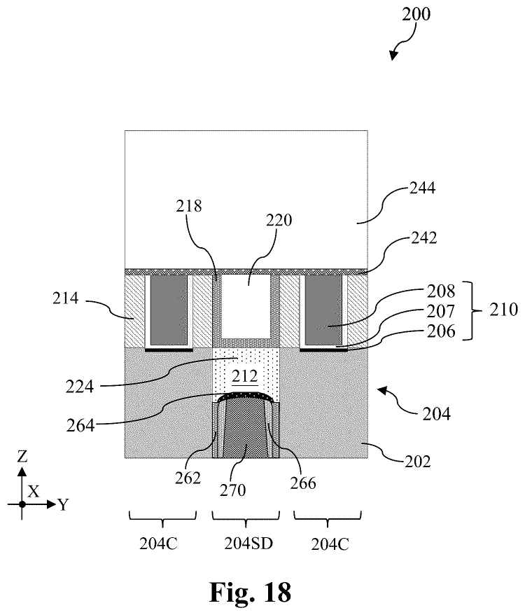

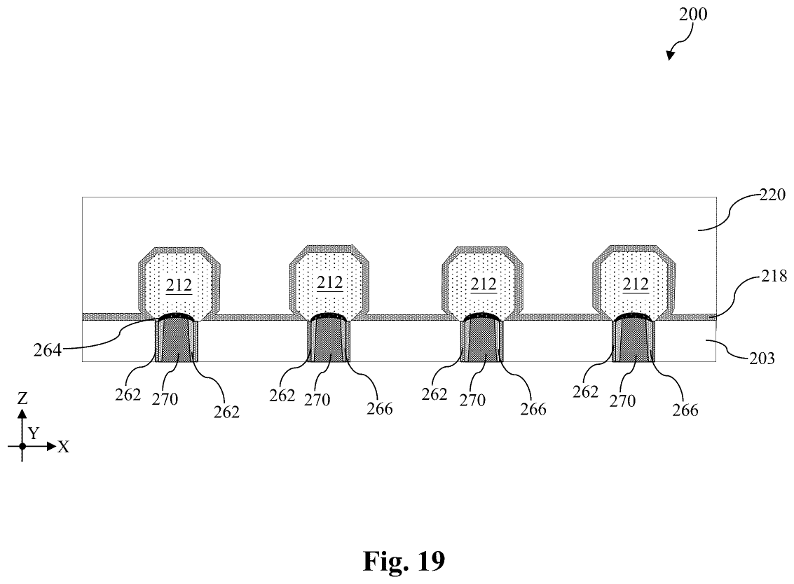

In some embodiments represented in FIGS. 18 and 19, the source/drain features 212 are accessed via backside contact plugs 270, rather then frontside contact plugs 250 shown in 15. A variant of method 100 may be used to form the via backside contact plugs 270. After the workpiece 200 is received, as shown in FIGS. 2 and 3, the workpiece 200 is flipped upside down for backside processing. In some embodiments, a thickness of the substrate 202 is reduced by grinding, polishing, or a combination thereof. In some embodiments, after the substrate is thinned, a backside trench is formed to expose a bottom surface of the source/drain feature 212. The formation of the backside trench may form a bottom recess on the source/drain feature 212. A first bottom CESL 262 and a first bottom ILD (removed and not shown) are formed in the backside trench. Then the first bottom ILD is isotropically etched in a wet etch process to form a backside source/drain access trench to expose a bottom surface and sidewalls of the source/drain feature 212. A backside silicide layer 264 is then formed to wrap over the bottom surface and sidewalls of the source/drain feature 212 from the back side. A second bottom CESL 266 and a second bottom ILD layer (removed and not shown) are then sequentially deposited over the backside source/drain access trench. A backside source/drain contact opening is then formed through the second bottom ILD layer to expose the backside silicide layer 264. A backside contact plug 270 is then formed in the backside source/drain contact opening. A planarization process, such as a CMP process, is performed to the back side of the workpiece 200 to remove access materials.

In the embodiments represented in FIGS. 18 and 19, the backside silicide layer 264 spans only over the second bottom CESL 266. For reasons similar to those described in conjunction with FIG. 16, the backside silicide layer 264 may also span over the first bottom CESL 262. In some alternative embodiments, the substrate 202 may be removed and replaced with a backside dielectric layer. The backside dielectric layer may have a composition similar to the isolation feature 203.

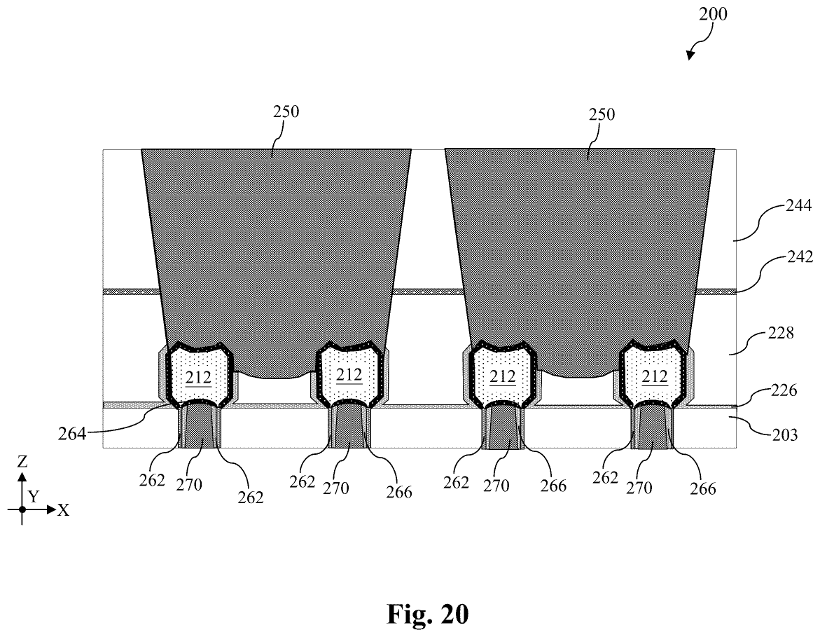

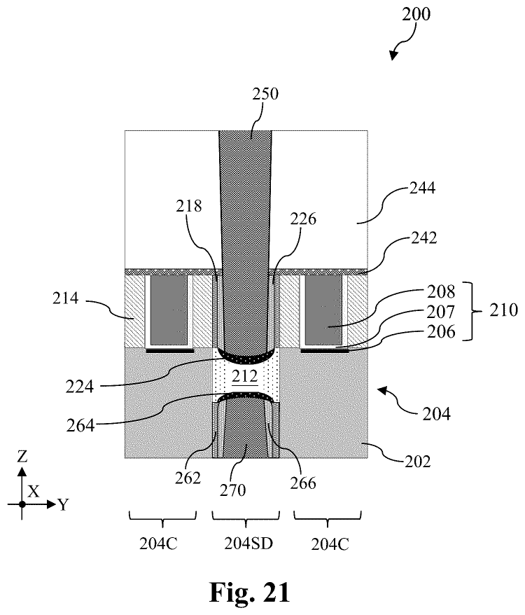

In some embodiments represented in FIGS. 20 and 21, the source/drain features 212 are accessed via both frontside contact plugs 250 and backside contact plugs 270. As described above in conjunction with FIGS. 2-15 and 18-19, operations in method 100 may be performed once to the front side of the workpiece 200 to form the contact plugs 250 and performed again to the back side of the workpiece 200 to form the backside contact plugs 270. Detailed description of the process steps to form the structures shown in FIGS. 20 and 21 are omitted for brevity. In the embodiments represented in FIGS. 20 and 21, each of the frontside contact plugs 250 engages two source/drain features 212 by way of the silicide layer 224 while each of the backside contact plugs 270 engages a single source/drain feature 212 by way of the backside silicide layer 264. Due to formation of the source/drain access trench 222 (shown in FIG. 4) and the backside trench, each of the source/drain features 212 has a top recess and a bottom recess.

In one exemplary aspect, the present disclosure is directed to a semiconductor structure. The semiconductor structure includes an active region extending along a first direction and including a first channel region, a second channel region, and a source/drain region sandwiched between the first channel region and the second channel region along the first direction, a first gate structure disposed over the first channel region and extending lengthwise along a second direction perpendicular to the first direction, a second gate structure disposed over the second channel region and extending lengthwise along the second direction, a source/drain feature disposed over the source/drain region, a first gate spacer disposed along a sidewall of the first gate structure, a second gate spacer disposed along a sidewall of the second gate structure, a first contact etch stop layer (CESL) disposed over a top surface of the source/drain feature and extending along sidewalls of the first gate spacer and the second gate spacer, a second CESL disposed over the top surface of the source/drain feature and extending along sidewalls of the first CESL, and a contact plug extending through the second CESL such that the second CESL is sandwiched between first CESL and the contact plug.

In some embodiments, the semiconductor structure further includes a silicide layer wrapping over the top surface and sidewalls if the source/drain feature. The contact plug is electrically coupled to the source/drain feature by way of the silicide layer. In some implementations, the silicide layer undercuts the second CESL. In some instances, the silicide layer further undercuts the first CESL. In some embodiments, the silicide layer extends between a sidewall of the source/drain feature and the second CESL. In some embodiments, top surfaces of the first gate structure, the second gate structure, the first gate spacer, the second gate spacer, the first CESL, and the second CESL are coplanar. In some instances, the semiconductor structure further includes an etch stop layer (ESL) disposed on and in contact with the top surfaces of the first gate structure, the second gate structure, the first gate spacer, the second gate spacer, the first CESL, and the second CESL. In some embodiments, a bottom surface of the second CESL extends further into the source/drain feature than a bottom surface of the first CESL.

In another exemplary aspect, the present disclosure is directed to a semiconductor structure. The semiconductor structure a channel region of a semiconductor body rising above an isolation feature, a gate structure wrapping over the channel region, a source/drain feature in contact with a sidewall of the channel region, a backside silicide layer disposed on a bottom surface of the source/drain feature, and a backside contact feature extending through the isolation feature to contact a bottom surface of the backside silicide layer. A sidewall of the backside contact feature is spaced apart from the isolation feature by a first backside contact etch stop layer (CESL) and a second backside CESL.

In some embodiments, the semiconductor structure further includes a gate spacer disposed along a sidewall of the gate structure, a first frontside CESL disposed over a top surface of the source/drain feature and extending along a sidewall of the gate spacer, a second frontside CESL disposed over the top surface of the source/drain feature and extending along a sidewalls of the first frontside CESL, and a contact plug extending along the second CESL to electrically coupled to the source/drain feature by way of a frontside silicide layer. In some implementations, the frontside silicide layer wraps over a top surface and sidewalls of the source/drain feature. In some embodiments, the first frontside CESL, the second frontside CESL, the first backside CESL, and the second backside CESL include silicon nitride. In some embodiments, the frontside silicide layer undercuts the second frontside CESL. In some instances, the frontside silicide layer further undercuts the first frontside CESL.

In yet another exemplary aspect, the present disclosure is directed to a method. The method includes receiving a workpiece that includes an active region extending along a first direction and including a first channel region, a second channel region, and a source/drain region sandwiched between the first channel region and the second channel region along the first direction, a first gate structure disposed over the first channel region and extending lengthwise along a second direction perpendicular to the first direction, a second gate structure disposed over the second channel region and extending lengthwise along the second direction, a source/drain feature disposed over the source/drain region, a first gate spacer disposed along a sidewall of the first gate structure, a second gate spacer disposed along a sidewall of the second gate structure, a first contact etch stop layer (CESL) disposed over a top surface of the source/drain feature and extending along sidewalls of the first gate spacer and the second gate spacer, a first interlayer dielectric (ILD) layer disposed over the first CESL. The method further includes etching the first ILD layer and the first CESL to form a source/drain access trench to exposes a top surface and sidewalls of the source/drain feature, after the etching, depositing a silicide layer to wrap over the top surface and sidewalls of the source/drain feature, depositing a second CESL layer over the source/drain access trench, including over the silicide layer, depositing an second ILD layer over the second CESL layer, etching the second ILD layer and the second CESL to form a source/drain contact opening to exposes a top surface of the source/drain feature, and forming a contact plug over the source/drain contact opening.

In some embodiments, the silicide layer includes TiSi, ZrSi, SbSi, BiSi, NiSi, SnSi, MoSi, or a combination thereof. In some implementations, the contact plug includes W, Ru, Co, Cu, Mo, TaN, or TiN. In some instances, the etching of the first ILD layer and the first CESL includes isotropically etching the first ILD layer, and anisotropically etching the first CESL to expose the top surface of the source/drain feature. In some embodiments, after the etching of the first ILD layer and the first CESL, a portion of the first CESL remains disposed along the sidewalls of the first gate spacer and the second gate spacer. In some implementations, the silicide layer extends between the top surface of the source/drain feature and a bottom surface of the second CESL.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an active region extending along a first direction and comprising a first channel region, a second channel region, and a source/drain region sandwiched between the first channel region and the second channel region along the first direction;
a first gate structure disposed over the first channel region and extending lengthwise along a second direction perpendicular to the first direction;
a second gate structure disposed over the second channel region and extending lengthwise along the second direction;
a source/drain feature disposed over the source/drain region;
a first gate spacer disposed along a sidewall of the first gate structure;
a second gate spacer disposed along a sidewall of the second gate structure;
a first contact etch stop layer (CESL) disposed over a top surface of the source/drain feature and extending along sidewalls of the first gate spacer and the second gate spacer;
a second CESL disposed over the top surface of the source/drain feature and extending along sidewalls of the first CESL; and
a contact plug extending through the second CESL such that the second CESL is sandwiched between first CESL and the contact plug.

2. The semiconductor structure of claim 1, further comprising:
a silicide layer wrapping over the top surface and sidewalls if the source/drain feature,
wherein the contact plug is electrically coupled to the source/drain feature by way of the silicide layer.

3. The semiconductor structure of claim 2, wherein the silicide layer undercuts the second CESL.

4. The semiconductor structure of claim 2, wherein the silicide layer further undercuts the first CESL.

5. The semiconductor structure of claim 2, wherein the silicide layer extends between a sidewall of the source/drain feature and the second CESL.

6. The semiconductor structure of claim 1, wherein top surfaces of the first gate structure, the second gate structure, the first gate spacer, the second gate spacer, the first CESL, and the second CESL are coplanar.

7. The semiconductor structure of claim 6, further comprising:
an etch stop layer (ESL) disposed on and in contact with the top surfaces of the first gate structure, the second gate structure, the first gate spacer, the second gate spacer, the first CESL, and the second CESL.

8. The semiconductor structure of claim 1, wherein a bottom surface of the second CESL extends further into the source/drain feature than a bottom surface of the first CESL.

9. A semiconductor structure, comprising:
a channel region of a semiconductor body rising above an isolation feature;
a gate structure wrapping over the channel region;
a source/drain feature in contact with a sidewall of the channel region;
a backside silicide layer disposed on a bottom surface of the source/drain feature; and
a backside contact feature extending through the isolation feature to contact a bottom surface of the backside silicide layer,
wherein a sidewall of the backside contact feature is spaced apart from the isolation feature by a first backside contact etch stop layer (CESL) and a second backside CESL.

10. The semiconductor structure of claim 9, further comprising:
a gate spacer disposed along a sidewall of the gate structure;
a first frontside CESL disposed over a top surface of the source/drain feature and extending along a sidewall of the gate spacer;
a second frontside CESL disposed over the top surface of the source/drain feature and extending along a sidewalls of the first frontside CESL; and
a contact plug extending along the second CESL to electrically coupled to the source/drain feature by way of a frontside silicide layer.

11. The semiconductor structure of claim 10, wherein the frontside silicide layer wraps over a top surface and sidewalls of the source/drain feature.

12. The semiconductor structure of claim 10, wherein the first frontside CESL, the second frontside CESL, the first backside CESL, and the second backside CESL comprise silicon nitride.

13. The semiconductor structure of claim 10, wherein the frontside silicide layer undercuts the second frontside CESL.

14. The semiconductor structure of claim 10, wherein the frontside silicide layer further undercuts the first frontside CESL.

15. A method, comprising:
receiving a workpiece comprising:
an active region extending along a first direction and comprising a first channel region, a second channel region, and a source/drain region sandwiched between the first channel region and the second channel region along the first direction,
a first gate structure disposed over the first channel region and extending lengthwise along a second direction perpendicular to the first direction,
a second gate structure disposed over the second channel region and extending lengthwise along the second direction,
a source/drain feature disposed over the source/drain region,
a first gate spacer disposed along a sidewall of the first gate structure,
a second gate spacer disposed along a sidewall of the second gate structure,
a first contact etch stop layer (CESL) disposed over a top surface of the source/drain feature and extending along sidewalls of the first gate spacer and the second gate spacer,
a first interlayer dielectric (ILD) layer disposed over the first CESL;
etching the first ILD layer and the first CESL to form a source/drain access trench to exposes a top surface and sidewalls of the source/drain feature;
after the etching, depositing a silicide layer to wrap over the top surface and sidewalls of the source/drain feature;
depositing a second CESL layer over the source/drain access trench, including over the silicide layer;
depositing an second ILD layer over the second CESL layer;
etching the second ILD layer and the second CESL to form a source/drain contact opening to exposes a top surface of the source/drain feature; and
forming a contact plug over the source/drain contact opening.

16. The method of claim 15, wherein the silicide layer comprises TiSi, ZrSi, SbSi, BiSi, NiSi, SnSi, MoSi, or a combination thereof.

17. The method of claim 15, wherein the contact plug comprises W, Ru, Co, Cu, Mo, TaN, or TiN.

18. The method of claim 15, wherein the etching of the first ILD layer and the first CESL comprises:
isotropically etching the first ILD layer; and
anisotropically etching the first CESL to expose the top surface of the source/drain feature.

19. The method of claim 15, wherein, after the etching of the first ILD layer and the first CESL, a portion of the first CESL remains disposed along the sidewalls of the first gate spacer and the second gate spacer.

20. The method of claim 15, wherein the silicide layer extends between the top surface of the source/drain feature and a bottom surface of the second CESL.
